(19) United States
(12) Patent Application Publication
(10) Pub. No.: US 2009/0311869 A1
(43) Pub. Date: Dec. 17, 2009

(54) SHOWER PLATE AND MANUFACTURING METHOD THEREOF, AND PLASMA PROCESSING APPARATUS, PLASMA PROCESSING METHOD AND ELECTRONIC DEVICE MANUFACTURING METHOD USING THE SHOWER PLATE

(75) Inventors: Masahiro Okesaku, Ishikawa (JP); Tetsuya Goto, Miyagi (JP); Tadahiro Ohmi, Miyagi (JP); Kiyotaka Ishibashi, Tokyo (JP)

Correspondence Address: PEARNE & GORDON LLP, 1801 EAST 9TH STREET, SUITE 1200, CLEVELAND, OH, 44114-3108, US

(73) Assignees: TOKYO ELECTRON LIMITED, Tokyo (JP); NATIONAL UNIVERSITY CORP. TOHOKU UNIVERSITY, Miyagi (JP)

(21) Appl. No.: 12/374,405

(22) PCT Filed: Jul. 18, 2007
(86) PCT No.: PCT/JP2007/064191

§ 371 Date: Jan. 20, 2009

(30) Foreign Application Priority Data
Jul. 20, 2006 (JP) 2006-198762
Jul. 12, 2007 (JP) 2007-182964

(51) Int. Cl. H01L 21/465; C23C 16/455; H05H 1/46; B29C 65/02

(52) U.S. Cl. 438/710; 118/723 R; 156/345.34; 427/575; 216/69; 264/241; 257/E21.485

(57) ABSTRACT

Provided is a shower plate capable of more securely preventing the occurrence of backflow of plasma and enabling efficient plasma excitation. A shower plate 106 is disposed in a processing chamber 102 of a plasma processing apparatus and is provided with a plurality of gas discharge holes 113a for discharging a plasma excitation gas to generate plasma in the processing chamber 102, wherein an aspect ratio of a length of the gas discharge hole to a hole diameter thereof (length/hole diameter) is equal to or greater than about 20. The gas discharge holes 113a are made of ceramics members 113 which are separated from the shower plate 106, and the ceramics members 113 are installed in vertical holes 105 opened in the shower plate 106.

### TECHNICAL FIELD

The present invention relates to a shower plate for use in a plasma processing apparatus, more particularly, in a microwave plasma processing apparatus and a manufacturing method thereof, and a plasma processing apparatus, a plasma processing method and an electronic device manufacturing method using the shower plate.

### BACKGROUND ART

A plasma process and a plasma processing apparatus are essential for the manufacture of a recent ultrafine semiconductor device called a deep sub-micron device or deep sub-quarter micron device having a gate length of about 0.1 μm or less, or the manufacture of a flat panel display of a high-resolution including a liquid crystal display.

Various plasma excitation methods are conventionally adopted for the plasma processing apparatus for use in the manufacture of the semiconductor device or the liquid crystal display. Especially, a high-frequency excitation plasma processing apparatus of a parallel plate type or an inductively coupled plasma processing apparatus is generally utilized. In the conventional plasma processing apparatus, however, since the plasma generation has been non-uniform and the electron density has been found to be high only in a limited region, it has been difficult to perform a uniform process over the entire surface of a target substrate with a high processing rate, i.e., with a high throughput. Especially, such problem becomes serious when processing a substrate having a large diameter. Besides, these conventional plasma processing apparatuses also have other essential problems such as the occurrence of damage on a semiconductor device formed on the target substrate due to the high electron temperature, the occurrence of a high level metal contamination due to the sputtering a processing chamber wall, and so forth. Accordingly, in the conventional plasma processing apparatus, it is getting more and more difficult to meet recent demands for further miniaturization of semiconductor devices or liquid crystal displays and enhancement of productivity.

Meanwhile, there has been conventionally proposed a microwave plasma processing apparatus which employs high-density plasma excited by a microwave electric field without using a DC magnetic field. For example, there has been proposed a plasma processing apparatus having a configuration in which microwave is emitted into a processing chamber from a planar antenna (radial line slot antenna) having a number of slots arranged to generate the microwave in a uniform manner, and plasma is excited by ionizing a gas in the processing chamber by an electric field of the microwave (see, for example, Patent Document 1). The microwave plasma excited by this method is capable of achieving high plasma density over a wide area directly under the antenna, and it is possible to perform a uniform plasma process in a short period of time. Further, in the microwave plasma generated by this method, the electron temperature is low because the plasma is generated by the microwave, and the damage or the metal contamination of the target substrate can be prevented. Moreover, since it is possible to easily excite the plasma uniformly even on a large-area substrate, the plasma processing apparatus can be effectively applied to a large-size liquid crystal display manufacturing process or a semiconductor device manufacturing process using a semiconductor substrate having a large diameter.

In such plasma processing apparatus, a shower plate having a plurality of gas discharge holes is typically used to uniformly supply a plasma excitation gas into the processing chamber. Due to the use of the shower plate, however, the plasma formed directly under the shower plate may flow backward through the gas discharge holes of the shower plate. If the plasma flows backward through the gas discharge holes, abnormal discharge or gas deposition takes place, resulting in deterioration of yield or transmission efficiency of the microwave for exciting the plasma.

As a means to prevent the backflow of the plasma toward the gas discharge holes, there have been proposed many improvements of the structure of the shower plate.

For example, Patent Document 2 discloses that it is effective to set the diameter of the gas discharge hole to be smaller than twice the sheath thickness of the plasma formed directly under the shower plate. However, reducing the diameter of the gas discharge hole is not sufficient as the means to prevent the backflow of the plasma. Especially, if plasma density is increased from about 10¹² cm⁻³, which is conventional plasma density, to about 10¹³ cm⁻³ for the purpose of reducing damage while increasing processing rate, the backflow of the plasma becomes dominant, so that its prevention cannot be achieved only by controlling the diameter of the gas discharge hole. Moreover, it is actually difficult to form the gas discharge hole having such fine hole diameter in a shower plate main body by a hole processing, so that there occurs a problem of processability.

Further, Patent Document 3 proposes using a shower plate made of a porous ceramics sintered body having gas permeable property. This tries to prevent the backflow of the plasma by the wall of a number of pores constituting the porous ceramics sintered body. However, in case of a shower plate made of a general porous ceramics sintered body sintered under normal temperature and pressure, the pore diameters have a great variability in size, ranging from several μm to about 20 μm. Further, since the maximum crystal diameter is as large as about 20 μm and the structure is not uniform, the surface flatness is poor. In addition, if the shower plate's surface making contact with the plasma is made of the porous ceramics sintered body, an effective surface area increases, so that recombination of electrons and ions of the plasma increases, resulting in deterioration of power efficiency of plasma excitation. Moreover, also disclosed in Patent Document 3 is a structure in which, instead of forming the entire shower plate with the porous ceramics sintered body, a general porous ceramics sintered body sintered under normal temperature and pressure is installed at gas discharge openings formed in a shower plate made of alumina having high density, and the gas is discharged through the porous ceramics sintered body. In this structure, however, since the plasma still makes contact with the general porous ceramics sintered body having substantially the same property as that of the porous ceramics sintered body sintered under the normal temperature and pressure, the aforementioned problems caused by the poor surface flatness still remain.

Further, in Patent Document 4, the present applicant has already proposed a means to prevent backflow of plasma by the control of a diameter size of gas discharge hole, and not by the structure of the shower plate. That is, by setting the diameter of the gas discharge hole to be less than about 0.1 to 0.3 mm, with the precision of diameter size tolerance within ±0.002 mm, the backflow of plasma is prevented, while removing variability of gas discharge amount.

However, when this shower plate was actually used in a microwave plasma processing apparatus under the condition of plasma density increased up to 10¹³ cm⁻³, discolored portions of light brown, which are considered to be the result of plasma backflow, were found in a space 402 formed between a shower plate main body 400 and a cover plate 401, for charging plasma excitation gas therein, and vertical holes 403 communicating with this space.

Patent Document 1: Japanese Patent-Laid-open Publication No. H9-63793

### Patent Document 2: Japanese Patent Laid-open Publication No. 2005-33167

### Patent Document 3: Japanese Patent Laid-open Publication No. 2004-39972

Patent Document 4: International Publication No. 06/112392 pamphlet

### DISCLOSURE OF THE INVENTION

### Problems to be Solved by the Invention

In view of the foregoing, the present invention provides a shower plate capable of more securely preventing the occurrence of backflow of plasma and enabling efficient plasma excitation.

### Means for Solving the Problems

The present inventors conducted researches under the thought that the backflow of plasma is affected by a ratio of the length of a gas discharge hole to the hole diameter thereof (length/hole diameter, hereinafter referred to as an “aspect ratio”). The present inventors finally reached a conclusion that the backflow of the plasma can be suppressed dramatically if the aspect ratio is set to be equal to or greater than about 20, and completed the present invention.

That is, in accordance with the present invention, there is provided a shower plate disposed in a processing chamber of a plasma processing apparatus and provided with a plurality of gas discharge holes for discharging a plasma excitation gas to generate plasma in the processing chamber, wherein an aspect ratio of the gas discharge hole is equal to or greater than about 20 in order to prevent the backflow of the plasma.

FIG. 1 is a diagram for explaining a relationship between the aspect ratio of the gas discharge hole and the backflow of the plasma. If the pressure in a processing chamber of a plasma processing apparatus decreases, a mean free path is lengthened, so that the distance where electrons constituting the plasma proceeds in a straight line is also increased. In this manner, on the assumption that the electrons travel in a straight line, an enterable angle θ of the plasma shown in FIG. 1 is determined solely by the aspect ratio of the gas discharge hole A. That is, if the aspect ratio of the gas discharge hole A is increased, the enterable angle θ of the plasma is reduced, resulting in prevention of the backflow of the plasma. The present invention clarifies necessary conditions of the aspect ratio of the gas discharge hole A based on this thought. As described, by setting the aspect ratio of the gas discharge hole A to be equal to or greater than about 20, the backflow of the plasma can be suppressed dramatically.

It is difficult to form a minutely narrow and long gas discharge hole having such aspect ratio as defined in the present invention in a shower plate main body by a hole processing method using a drill or other machining tools, and a processability problem also arises. In the present invention, a ceramics member having one or a plurality of gas discharge holes is installed in a multiplicity of vertical holes of a shower plate. That is, the gas discharge holes are formed in the ceramics member which is separated from the shower plate, and this ceramics member is installed in the vertical hole opened in the shower plate. With this configuration, a yield loss of the shower plate due to processing errors of the gas discharge holes can be suppressed in comparison with the case of forming the gas discharge holes in the shower plate by a hole processing, and the minute and long gas discharge holes having the aspect ratio defined in the present invention can be easily formed. Furthermore, the ceramics member having the gas discharge holes can be formed by an injection molding, an extrusion molding, a special cast molding, or the like.

As for a specific size of the gas discharge hole, it is desirable that the diameter thereof is equal to or less than twice a sheath thickness of the plasma generated directly under the shower plate, and the length of the gas discharge hole is longer than a mean free path of electrons in the processing chamber.

Further, a plasma excitation gas can be supplied into a plasma processing apparatus by using a shower plate in accordance with the present invention; plasma can be generated by exciting the supplied plasma excitation gas by microwave; and oxidation, nitridation, oxynitridation, CVD, etching or plasma irradiation can be performed on a substrate by using the plasma.

Furthermore, a shower plate in accordance with the present invention, which includes a vertical hole provided with a ceramics member having one or more gas discharge holes, can be manufactured by inserting a green body, a debound body, a tentatively sintered body or a sintered body of a ceramics member having one or more gas discharge holes into a vertical hole of a green body, a debound body or a tentatively sintered body of a shower plate having the vertical hole formed by molding raw material powder, and then sintering them at the same time. Further, it can be manufactured by inserting, together with the ceramics member, a green body, a debound body, a tentatively sintered body or a sintered body of a porous gas flowing body into a vertical hole, and then sintering them at the same time.

### EFFECT OF THE INVENTION

In accordance with the present invention, the backflow of the plasma through the vertical hole portion of the shower plate can be prevented, and the abnormal discharge or the deposition of gas inside the shower plate can be suppressed. Therefore, the deterioration of yield or transmission efficiency of microwave for exciting plasma can be prevented.

### BEST MODE FOR CARRYING OUT THE INVENTION

Hereinafter, examples of the present invention will be described based on embodiments.

### First Embodiment

FIG. 2 shows a first embodiment of the present invention. Referring to FIG. 2, a microwave plasma processing apparatus is illustrated. The illustrated microwave plasma processing apparatus includes a processing chamber 102 evacuated through a plurality of gas exhaust ports 101, and a holding table 104 for holding a target substrate 103 is disposed in the processing chamber 102. The processing chamber 102 defines a ring-shaped space around the holding table 104 in order to evacuate the processing chamber 102 uniformly, and the plurality of gas exhaust ports 101 is arranged at a same interval, i.e., in axial symmetry with respect to the target substrate 103, while communicating with the space. With such arrangement of the gas exhaust ports 101, the processing chamber 102 can be evacuated through the gas exhaust ports 101 uniformly.

Disposed at an upper portion of the processing chamber 102 via a sealing O-ring 107 is a plate-shaped shower plate 106 which has a diameter of about 408 mm and a dielectric constant of about 9.8, and is made of dielectric alumina having a low microwave dielectric loss (equal to or less than about 9×10⁻⁴, desirably equal to or less than about 5×10⁻⁴). The shower plate 105 is installed at a position corresponding to the target substrate 103 on the holding table 104, and constitutes a part of an exterior wall of the processing chamber 102. The shower plate 105 is provided with a number of (e.g., 230) openings, i.e., vertical holes 105. Further, in the processing chamber 102, a cover plate 108 made of alumina is installed via a sealing O-ring 109 on the top surface side of the shower plate 106, i.e., on the opposite side from the holding table 104 with respect to the shower plate 106.

FIG. 3 sets forth a schematic perspective view to show arrangement of the shower plate 106 and the cover plate 108. Referring to FIGS. 2 and 3, formed between the top surface of the shower plate 106 and the cover plate 108 are spaces 112 for charging therein a plasma excitation gas supplied from a gas supply port 110 for the plasma excitation gas via a gas supply hole 111 communicating therewith and opened to the inside of the shower plate 106. In other words, in the cover plate 108, grooves are formed in the cover plate 108's surface in contact with the shower plate 106 at positions corresponding to the vertical holes and the gas supply hole 111 so as to be connected with them, and the spaces 112 are formed between the shower plate and the cover plate 108. That is, the vertical holes are disposed to communicate with the spaces 112.

FIGS. 4A to 4C illustrate detailed views of the vertical hole 105. In FIGS. 4A to 4C, FIG. 4A is a cross sectional view, and FIGS. 4B and 4C are bottom views. The vertical hole 105 includes a first vertical hole 105a having a diameter of about 2.5 mm and a height of about 1 mm provided on the side of the processing chamber 102; and a second vertical hole 105b having a diameter of about 3 mm and a height of about 8 mm provided on the front part thereof (i.e., on the gas introducing side). Further, a ceramics member 113 is installed in the vertical hole 105. The ceramics member 113 is made of an extrusion molding product of alumina-based ceramics, and its portion located in the first vertical hole 105a has an outer diameter of about 2.5 mm and a length of about 1 mm while its portion located in the second vertical hole 105b has an outer diameter of about 3 mm and a length of about 7 mm, and the whole length thereof is about 8 mm. Installed therein is a gas discharge hole 113a having a diameter of about 0.05 mm and a length of about 8 mm. That is, the aspect ratio (length/hole diameter) of the gas discharge hole 113a is about 8/0.05=160. There is no special restriction in the number of the gas discharge holes 113a. Though FIGS. 4B and 4C show examples in which the number of the gas discharge holes is 7 and 3, respectively, it is more desirable to increase the number thereof as many as possible in order to reduce a gas discharge rate. Further, as in this example, if the diameter of the gas discharge hole 113a is reduced to about 0.05 mm, it may be possible to reduce the outer diameter of the ceramics member 113 to about 1 mm.

FIGS. 5A and 5B illustrate another example of the vertical hole 105. In FIGS. 5A and 5B, FIG. 5A is a cross sectional view and FIG. 5B is a bottom view. In this example, only one gas discharge hole 113a having a diameter of about 0.2 mm and a length of about 8 to 10 mm is provided.

FIGS. 6A and 6B illustrate still another example of the vertical hole 105. In FIGS. 6A and 6B, FIG. 6A is a cross sectional view and FIG. 6B is a bottom view. In FIGS. 6A and 6B, the vertical hole 105 includes, from the side of the processing chamber 102, a first vertical hole 105a having a diameter of about 5 mm and a height of about 5 mm; and a second vertical hole 105b having a diameter of about 10 mm and a height of about 10 mm, and installed in this vertical hole 105 is a columnar ceramics member 113 having a total height of about 8 mm and provided with six gas discharge holes 113a each having a diameter of about 0.05 mm.

Further, as for each of the vertical holes 105 shown in FIGS. 4A to 6B, a chamfering process 115 is performed on its corner portion at the gas introducing side thereof to prevent self-generation of plasma as a result of concentration of microwave electric field thereat and ignition of the plasma excitation gas. The chamfering process may be a C-chamfering process, more desirably, an R-chamfering process, and it may be also possible to perform the R-chamfering process after the C-chamfering process is performed on its angled portion.

Further, FIGS. 6A and 6B show an example in which a porous ceramics sintered body 114 provided with pores communicating in a gas flow direction is installed at the gas introducing side of the ceramics member 113 in order to prevent the backflow of the plasma more securely or to eliminate a space where self-generation of plasma occurs by the ignition of the plasma excitation gas.

Now, a method for introducing the plasma excitation gas into the processing chamber will be explained with reference to FIG. 2. The plasma excitation gas from the gas inlet port 110 is introduced into the vertical holes 105 via the gas supply hole 111 and the spaces 112, and is discharged into the processing chamber 102 from the gas discharge holes 113a of the ceramics member 113 disposed at leading end portions thereof.

Provided on the top surface of the cover plate 108 covering the top surface of the shower plate 106 are a slot plate 116 of a radial line slot antenna opened by a number of slits for radiating microwave; a wavelength shortening plate 117 for propagating the microwave in a diametric direction, and a coaxial waveguide 118 for introducing the microwave into the antenna. Further, the wavelength shortening plate 117 is interposed between the slot plate 116 and a metal plate 119. The metal plate 119 is provided with a cooling flow path 120.

With this configuration, the plasma excitation gas supplied from the shower plate 106 is ionized by the microwave radiated from the slot plate 116, so that high-density plasma is generated in an area within several millimeters directly under the shower plate 106. The generated plasma reaches the target substrate 103 by the diffusion. Besides the plasma excitation gas, a gas for actively generating radicals, e.g., an oxygen gas or an ammonia gas may also be introduced from the shower plate 106.

In the illustrated plasma processing apparatus, a lower shower plate 121 made of a conductor such as aluminum, stainless steel or the like is disposed between the shower plate 106 and the target substrate 103 in the processing chamber 102. The lower shower plate 121 includes a plurality of gas flow paths 121a through which a processing gas supplied from a processing gas supply port 122 is provided to the target substrate 103 in the processing chamber 102, and the processing gas is discharged into a space between the lower shower plate 121 and the target substrate 103 through a multiplicity of nozzles 121b formed in gas flow paths 121a's surfaces facing the target substrate 103. Here, in case of a plasma-enhanced chemical vapor deposition (PECVD) process, a silane gas or a disilane gas is introduced as the processing gas when forming a silicon-based thin film, whereas a C₅F₈ gas is introduced when forming a low dielectric film. Furthermore, a CVD process using an organic metal film as the processing gas is also possible. Further, in case of a reactive ion etching (RIE) process, a C₅F₈ gas and an oxygen gas are introduced when etching a silicon oxide film, whereas a chlorine gas or a HBr gas is introduced when etching a metal film or silicon. When ion energy is needed for the etching, an RF power supply 123 is connected to an electrode inside the holding table 104 via a capacitor, and a self-bias voltage is generated on the target substrate 103 by applying an RF power thereto. The kind of the flowing processing gas is not limited to the above-mentioned examples, but the kind of the flowing gas and the pressure can be determined depending on the process.

The lower shower plate 121 is provided with an opening 121c between the neighboring gas flow paths 121a. The opening 121c has a size capable of allowing the plasma, which is excited by the microwave in the region above the lower shower plate 121, to pass therethrough effectively so as to be diffused into the space between the target substrate 103 and the lower shower plate 121.

Further, a heat flow introduced into the shower plate 106 as a result of the exposure to the high-density plasma is cooled by a coolant such as water flowing through the cooling flow path 120 via the slot plate 116, the wavelength shortening plate 117 and the metal plate 119.

Referring again to FIGS. 4A to 4C, the plurality of gas discharge holes 113a illustrated in FIGS. 4A to 4C, which is opened in the columnar ceramics member 113 made of alumina material, has a diameter of about 0.05 mm as described above. This value is smaller than twice the sheath thickness 0.04 μm of the high-density plasma of about 10¹² cm⁻³, but larger than twice the sheath thickness 0.01 μm of the high-density plasma of about 10¹³ cm⁻³.

Further, the thickness d of the sheath formed on the surface of an object in contact with the plasma is obtained from the following equation.

$$d = 0.606 {{λ}_{D} ( \frac{2 {V}_{0}}{{T}_{e}} )}^{3 / 4} \qquad [ Eq . 1 ]$$

Here, V₀ represents a potential difference (V) between the plasma and the object; Tₑ indicates an electron temperature (eV); and λ_{D} is the Debye length calculated by the following equation.

$${λ}_{D} = \sqrt{\frac{{ɛ}_{0} {kT}_{e}}{{n}_{e} {e}^{2}}} = 7.43 \times {10}^{3} \sqrt{\frac{{T}_{e} [ eV ]}{{n}_{e} [ {m}^{- 3} ]}} [ m ] \qquad [ Eq . 2 ]$$

Here, ∈₀ indicates a vacuum permeability; k represents a Boltzmann constant, and nₑ stands for an electron density of the plasma.

As shown in Table 1, if the electron density of the plasma increases, the Debye length decreases. Thus, it can be said that the smaller the hole diameter of the gas discharge hole 113a is, the more desirable it is in the aspect of preventing the backflow of the plasma.

TABLE 1
Te = 2 eV, V₀ = 12 V

| Plasma Density (cm⁻³) | Debye Length (mm) | Sheath Thickness (mm) |
|---|---|---|
| 10¹³ | 0.003 | 0.01 |
| 10¹² | 0.011 | 0.04 |
| 10¹¹ | 0.033 | 0.13 |
| 10¹⁰ | 0.105 | 0.41 |

Further, by setting the length of the gas discharge hole 113a to be longer than a mean free path, which is a mean distance for electrons to travel before electrons are scattered, the backflow of the plasma can be greatly reduced. In Table 2, mean free paths of electrons are provided. The mean free path is in inverse proportion to the pressure, and it becomes 4 mm at 0.1 Torr. Though the mean free path actually becomes shorter than 4 mm because the pressure at the gas introducing side of the gas discharge hole 113a is high, in FIGS. 4A to 4C, the length of the gas discharge hole 113a having the diameter of about 0.05 mm is set to be mm, which is longer than the mean free path.

TABLE 2
Mean free path of electrons under Ar gas atmosphere

| Pressure (P) | Mean free path (λen) |
|---|---|
| (Torr) | (mm) |
| 10 | 0.04 |
| 1 | 0.4 |
| 0.1 | 4 |

λen(mm) = 0.4/P(Torr)

Here, since the mean free path is literally a mean distance, it should be noted that there statistically exist electrons which proceed a longer distance without being scattered. Accordingly, as shown in FIGS. 6A and 6B, the porous ceramics sintered body 114 having pores communicating in the gas flow direction may be formed at the gas introducing side of the gas discharge holes 113a to prevent any possible backflow of the plasma more securely.

To suppress a backflow of plasma through the pores and an abnormal discharge in the second vertical hole 105b, the pore diameter of the porous ceramics sintered body 114 is desirably set to be equal to or less than twice the sheath thickness of the high-density plasma formed directly under the shower plate 106, and more desirably equal to or less than the sheath thickness. The average pore diameter of the porous ceramics sintered body 114 in FIGS. 6A and 6B is equal to or less than about 10 μm, more desirably, equal to or less than about 5 μm, and this value is equal to or less than about 10 μm, which is the sheath thickness of the high-density plasma of 10¹³ cm⁻³. With this configuration, the present shower plate can also be adopted for the high-density plasma of 10¹³ cm⁻³.

With the shower plate 106 having the above-described configuration, the backflow of the plasma toward the gas introducing side of the vertical holes 105 can be prevented, and the generation of abnormal discharge or gas deposition inside the shower plate 105 can be suppressed. Therefore, the deterioration of yield or transmission efficiency of the microwave for exciting the plasma can be prevented. Furthermore, an efficient plasma excitation is enabled without reducing the flatness of the surface in contact with the plasma. Besides, since the gas discharge holes 113a are formed in the ceramics member 113 separate from the shower plate 105 by the extrusion molding method or the like, long and minute gas discharge holes can be more easily formed in comparison with a case of forming the gas discharge holes in the shower plate by a hole processing.

Further, as a result of supplying the plasma excitation gas to the target substrate 103 uniformly and discharging the processing gas to the target substrate 103 from the lower shower plate 121 via the nozzles 121b, there is generated a uniform flow of the processing gas from the nozzles 121b of the lower shower plate 121 toward the target substrate 103, resulting in a reduction of processing gas components returning to the upper portion of the shower plate 106. As a consequence, decomposition of processing gas molecules as a result of excessive dissociation due to exposure to the high-density plasma can be suppressed, and deterioration of the microwave introducing efficiency due to deposition of the processing gas onto the shower plate 106 is unlikely to occur, though the processing gas is a deposition gas. Therefore, the time of the cleaning process can be shortened, while the process stability and reproducibility can be improved, resulting in enhancement of productivity and realization of high-quality substrate processing.

Besides, in the present embodiment, the numbers, the diameters and the lengths of the first vertical holes 105a and the second vertical holes 105b, and the number, the diameter and the length of the gas discharge holes 113a opened in the ceramics member 113 are not limited to the present embodiment.

### Second Embodiment

FIG. 7 illustrates a second embodiment of the present invention. Referring to FIG. 7, a microwave plasma processing apparatus is illustrated. Parts identical to those described in the first embodiment will be assigned like reference numerals, and description thereof will be omitted.

In the present embodiment, disposed at an upper portion of a processing chamber 102 via a sealing O-ring 107 is a shower plate 200 which has a dielectric constant of about 9.8, and is made of dielectric alumina having a low microwave dielectric loss (equal to or less than about 9×10⁻⁴). The shower plate 200 is installed at a position corresponding to a target substrate 103 on a holding table 104, and constitutes a part of an exterior wall of the processing chamber 102. Further, at a wall surface 201 constituting the processing chamber 102, a ring-shaped space 203 surrounded by two sealing O-rings 202 and the lateral surface of the shower plate 200 is provided at a position corresponding to the lateral side of the shower plate 200. The ring-shaped space 203 communicates with the gas inlet port 110 for introducing a plasma excitation gas.

Meanwhile, a multiplicity of horizontal holes 204 each having a diameter of about 1 mm is provided in the lateral side of the shower plate 200 so as to be opened toward the center of the shower plate 200 in horizontal direction. At the same time, a number (e.g., about 230) of vertical holes 205 is opened to communicate with the processing chamber 102 as well as with the horizontal holes 204.

FIG. 8 illustrates the arrangement of the horizontal holes 204 and the vertical holes 205 of the shower plate 200, when viewed from the top. FIG. 9 is a schematic perspective view showing the arrangement of the horizontal holes 204 and the vertical holes 205. Further, FIG. 10 shows another detailed example of the vertical hole 205. The vertical hole 205 includes a first vertical hole 205a having a diameter of about 10 mm and a depth of about 8 mm provided on the side of the processing chamber 102; and a second vertical hole 205b having a diameter of about 1 mm provided on the front part thereof (i.e., on the gas introducing side), and communicates with the horizontal hole 204. Further, installed in the first vertical hole 205a in sequence, when viewed from the side of the processing chamber 102, are the ceramics member 113, which has a height of about 6 mm and made of alumina extrusion molding product and opened through the plurality of gas discharge holes 113a each having a diameter of about 0.05 mm; and the porous ceramics sintered body 114 of a columnar shape, which has a diameter of about 10 mm and a height of about 2 mm and provided with pores communicating in a gas flow direction. That is, in the present embodiment, the aspect ratio (length/hole diameter) of the gas discharge hole 113a is about 6/0.05=120.

In the present embodiment, the plasma excitation gas from the gas inlet port 110 is introduced into the ring-shaped space 203 and finally introduced into the processing chamber 102 through the gas discharge holes 113a, which are provided at leading end portions of the vertical holes 205, via the horizontal holes 204 and the vertical holes 205.

In this embodiment, similar effects to those obtained in the first embodiment can also be achieved.

Further, in the present embodiment, the numbers, the diameters and the lengths of the first vertical holes 205a and the second vertical holes 205b, and the number, the diameter and the length of the gas discharge holes 113a opened in the ceramics member 113 are not limited to the present embodiment. Moreover, the porous ceramics sintered body installed at the gas introducing side of the gas discharge holes 113a is not an essential component.

### Third Embodiment

FIG. 11 illustrates another embodiment of a vertical hole of the shower plate in accordance with the present invention. Parts identical with those described in the first and second embodiments will be assigned like reference numerals.

In the embodiment of FIG. 11, installed in a second vertical hole 105b (or 205b) is a ceramics member 113′ having a diameter of about 1 mm and a length of about 4 mm and provided with six gas discharge holes 113a′ each having a diameter of about 0.05 mm, and installed in a first vertical hole 105a (or 205a) is a ceramics member 113 having an outer diameter of about 7 mm and a height of about 2 mm and provided with sixty-one gas discharge holes 113a each having a diameter of about 0.05 mm. Further, a recess 300 having a diameter of about 5 mm and a depth of about 0.2 mm is provided at the gas introducing side of the ceramics member 113. A plasma excitation gas discharged from the six gas discharge holes 113a′ is diffused into and filled in the recess 300 and then discharged from the sixty-one gas discharge holes 113a. That is, since a rate of the gas discharged through the sixty-one gas discharge holes 113a is reduced to about 1/10 of a rate of the gas flowing through the six gas discharge holes 113a′, the plasma excitation gas is slowly discharged from the wide surface of the ceramics member 113 toward a processing chamber 102, so that uniform plasma without a turbulent flow can be generated. Further, a porous ceramics sintered body 114 as used in FIGS. 6A and 6B may be employed in lieu of the ceramics member 113.

The shower plates including the aforementioned ceramics members 113 and 113′ installed in the vertical holes in respective embodiments can be manufactured by the following methods.

### First Manufacture Example

About 100 parts by mass of Al₂O₃ powder having an average particle diameter of about 0.6 μm and a purity of about 99.99% was mixed and kneaded with about 5 parts by mass of extrusion molding binder and 15 parts by mass of moisture. Then, the mixture was extruded from a preset extrusion molding nozzle and dried, so that a ceramics member green body provided with lower holes of gas discharge holes (i.e., holes to become gas discharge holes after the sintering) was obtained.

A debound body obtained by heating the ceramics member green body at about 400 to 600° C., a tentatively sintered body obtained by heating the ceramics member green body at about 600 to 1200° C., a preliminarily sintered body obtained by sintering the ceramics member green body at about 1200 to 1400° C. (at which relative density reaches about 95%), and a sintered body sintered so as to obtain a relative density equal to or higher than about 95% were prepared. Further, measured were a heating shrinkage rate at each heating temperature (sintering temperature) and a size after the heating. Further, when performing the sintering at the same temperature as the sintering temperature of the shower plate, a sintering shrinkage rate was measured to be about 18.8% for the green body.

Meanwhile, as a shower plate material, a spray-dried and granular powder, which has an average particle diameter of about 70 μm and is obtained by mixing Al₂O₃ powder having an average particle diameter of about 0.6 μm and a purity of about 99.99% with 3 mass % of wax, was press-molded at various levels of pressure ranging from about 78 to 147 MPa, and then by molding and processing it to have preset sizes of outer diameter, thickness, horizontal holes and vertical holes, a shower plate green body was prepared. Further, the sintering shrinkage rate of this shower plate green body varied depending on the press-molding pressure. In addition, the sintering shrinkage rate was about 19% at 78 MPa, while it was about 16.2% at 147 MPa.

Here, the ceramics member green body (whose outer diameter corresponding to the second vertical hole 105b of FIGS. 4A to 4C is about 3.695 mm) was installed in a vertical hole (whose inner diameter corresponding to the second vertical hole 105b of FIGS. 4A to 4C is about 3.7 mm) of the shower plate green body, which was press-molded at the pressure of about 78 MPa, and they were simultaneously sintered at a temperature of about 1500° C. As a result, the shower plate shown in FIGS. 4A to 4C in the first embodiment was obtained.

At this time, the size of the second vertical hole 105b after the sintering is calculated to have inner diameter×(100%−19%)=3.7×0.81=2.997 mm. Likewise, the outer diameter of the ceramics member corresponding to the second vertical hole 105b becomes 3.695×0.812=3.000 mm. The difference 0.003 mm between the inner diameter and the outer diameter corresponding to the second vertical hole 105b functions as a heat fixing force between them, so that a sintering binding force between them is generated, and firm installation and fixing can be achieved.

### Second Manufacture Example

The same shower plate green body as prepared in the first manufacture example and a debound body, which is heated at 450° C. and hardly suffers a heating shrinkage, were prepared, and the debound body, the tentatively sintered body, the preliminarily sintered body and the sintered body for the ceramics member, which were prepared in the first manufacture example, were installed in each vertical hole, and their sintering was performed at the same time. In the present manufacture example, as in the first manufacture example, the debound body and the shower plate green body having the inner diameter of about 3.7 mm corresponding to the second vertical hole 105b shown in FIGS. 4A to 4C of the first embodiment were used. Further, the sintering shrinkage rates of the debound body, the tentatively sintered body, the preliminarily sintered body and the sintered body of the ceramics member installed in the vertical hole 105, and their sizes after the sintering were measured in advance. Then, utilized is a ceramics member of which outer diameter corresponding to the second vertical hole 105b becomes larger than the inner diameter of the second vertical hole 105b by at least 1 μm after the sintering of these ceramics members. Accordingly, such size difference functions as the heat fixing force, and as the sintering binding force corresponding to this heat fixing force increases, crystalline particles in the installation interface layer form an integrated continuous phase.

Further, heat fixing stress, which corresponds to a size difference of about 0.103 mm (equal to or greater than about 100 μm), is generated by installing, in the vertical hole, a ceramics member allowing an outer diameter of its sintered body corresponding to the second vertical hole 105b to be about 3.1 mm, and sintering them at the same time. The majority of heat fixing stress is absorbed into the shower plate side by a dislocation of constituent crystalline particles, a diffusion sintering or a slight degree of plastic flow, while only a part of heat fixing stress is absorbed into the ceramics member. As a result, both the shower plate and the ceramics member can be firmly installed without suffering a damage or a crack due to a tensile stress or a compression stress.

### Third Manufacture Example

The shower plate shown in FIGS. 4A to 4C of the first embodiment was manufactured by installing a tentatively sintered body or a sintered body of a ceramics member, whose heat fixing force corresponds to a size difference ranging from about 1 to 100 μm, in a vertical hole of a tentatively sintered body obtained by heating, at a temperature ranging from about 600 to 1200° C., a shower plate green body, which was obtained in the above-described first and second manufacture examples and molded at a press-molding pressure of about 147 MPa and whose sintering sizes was examined.

Further, by installing the sintered body of the ceramics member in a vertical hole of a preliminarily sintered body which is obtained by heating the shower plate green body to have a relative density ranging from about 95 to 97% and performing a HIP process at 1450° C. under a non-reactive gas atmosphere having a pressure of about −1500 kg/cm², a simultaneously sintered firm installation can be accomplished.

Moreover, as for the sizes and shapes of the vertical holes of the shower plate and the ceramics member, it is desirable that they are formed in a straight shape, as shown in FIG. 10 of the second embodiment, i.e., in a manner that the outer diameter of the ceramics member becomes a columnar shape. Thus, they can be manufactured simply, and their installation and simultaneous sintering can be facilitated.

### Fourth Manufacture Example

As for the porous gas flowing body, a tentatively sintered powder is obtained by heating, at a temperature of about 80° C., a spray-dried and granular powder, which has an average particle diameter of about 70 μm and is obtained by mixing Al₂O₃ powder having an average particle diameter of about 0.6 μm and purity of about 99.99% with 3 mass % of wax. Then, 3 mass % of Al₂O₃ powder for the shower plate is added and mixed, and the mixture is press-molded, so that a green body is obtained. Then, by sintering the green body, there is obtained a material for the porous gas flowing body having a narrow passage whose pore diameter is about 2 μm in a gas flow path formed by communicating pores; a dielectric loss of about 2.5×10⁻⁴; an average crystal diameter of about 1.5 μM; a maximum crystal diameter of about 3 μM; a porosity of about 40%; an average pore diameter of about 3 μM; a maximum pore diameter of about 5 μM; and a flexural strength of about 300 MPa.

A tentatively sintered body or a sintered body, which is obtained by sintering the green body for the porous gas flowing body at a temperature equal to or higher than about 1200° C., is processed to have a preset outer diameter and thickness, and then it is cleansed by a ultrasonic cleaning. Then, by installing it in a vertical hole of a green body or a debound body for the shower plate in a similar way to those described in the first to third manufacture examples and then simultaneously sintering them, the shower plate as shown in FIGS. 6A, 6B and 10 can be obtained.

### INDUSTRIAL APPLICABILITY

The shower plate of the present invention is applicable to various plasma processing apparatuses such as a high frequency excitation plasma processing apparatus of a parallel plate type, an inductively coupled plasma processing apparatus, and so forth, in addition to the microwave plasma processing apparatus.

### BRIEF DESCRIPTION OF THE DRAWINGS

FIG. 1 is a diagram for explaining a relationship between an aspect ratio of a gas discharge hole and a backflow of plasma;

FIG. 2 is a first embodiment of the present invention;

FIG. 3 is an arrangement of horizontal holes and vertical holes of a shower plate shown in FIG. 2;

FIGS. 4A to 4C are detailed views of a vertical hole of the shower plate shown in FIG. 2;

FIGS. 5A and 5B show another example of the vertical hole;

FIGS. 6A and 6B show still another example of the vertical hole;

FIG. 7 is a second embodiment of the present invention;

FIG. 8 is an arrangement of horizontal holes and vertical holes of a shower plate shown in FIG. 7 viewed from the top;

FIG. 9 is an arrangement of the shower plate and a cover plate shown in FIG. 7;

FIG. 10 is a detailed view of a vertical hole of the shower plate shown in FIG. 7;

FIG. 11 shows another example of a vertical hole in the shower plate of the present invention; and

FIG. 12 is a conventional shower plate.

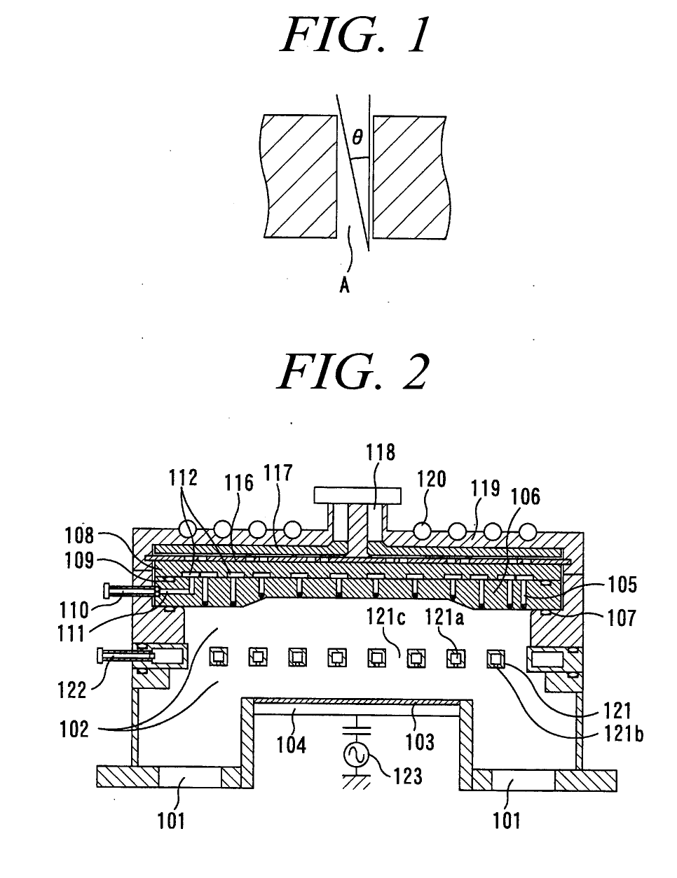

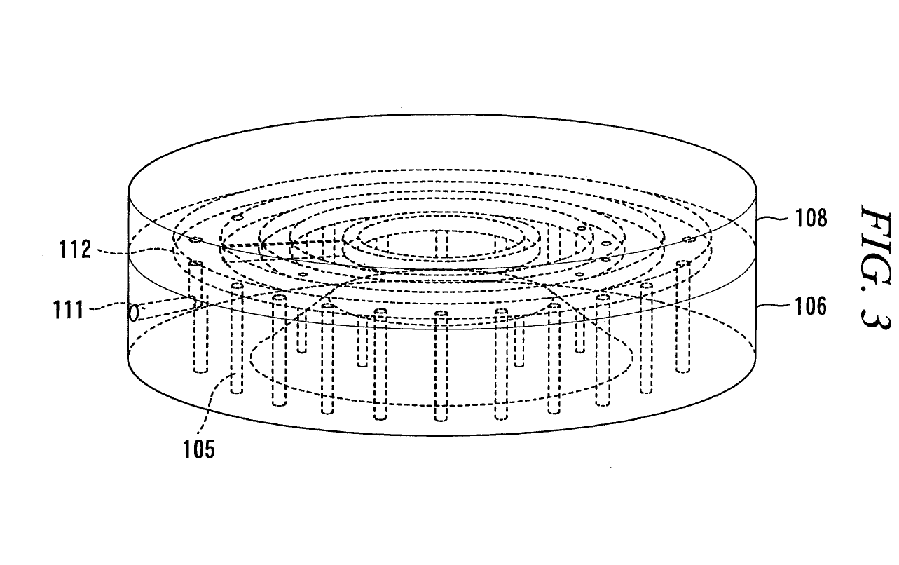

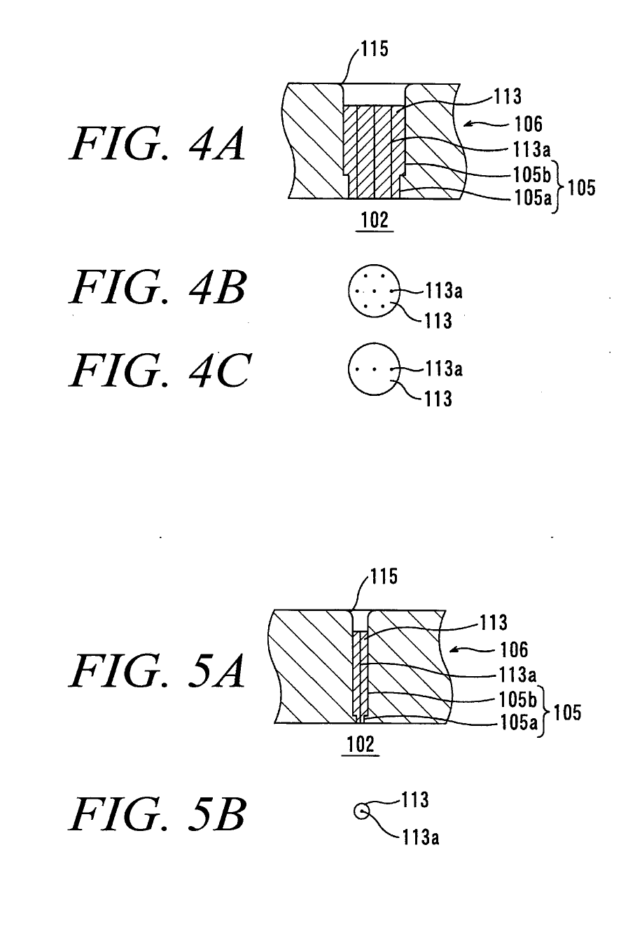

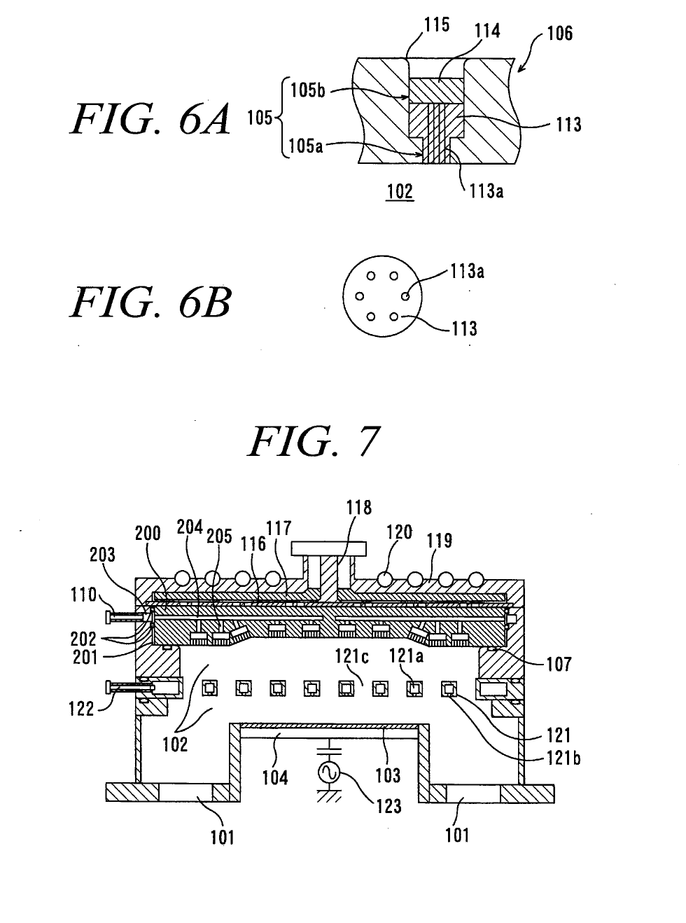

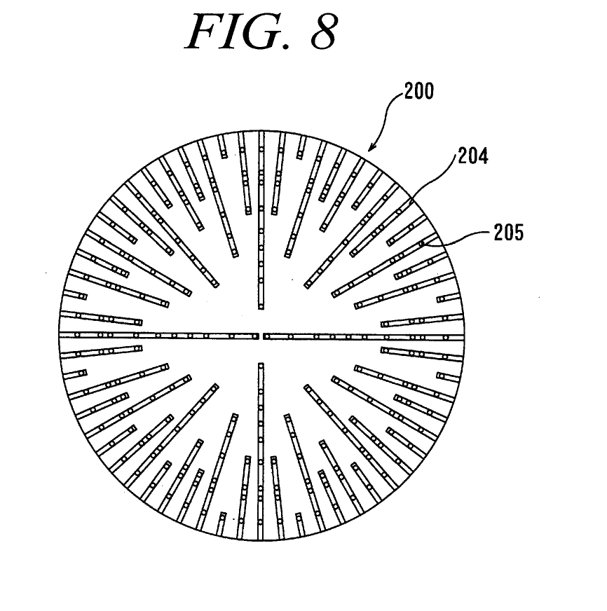

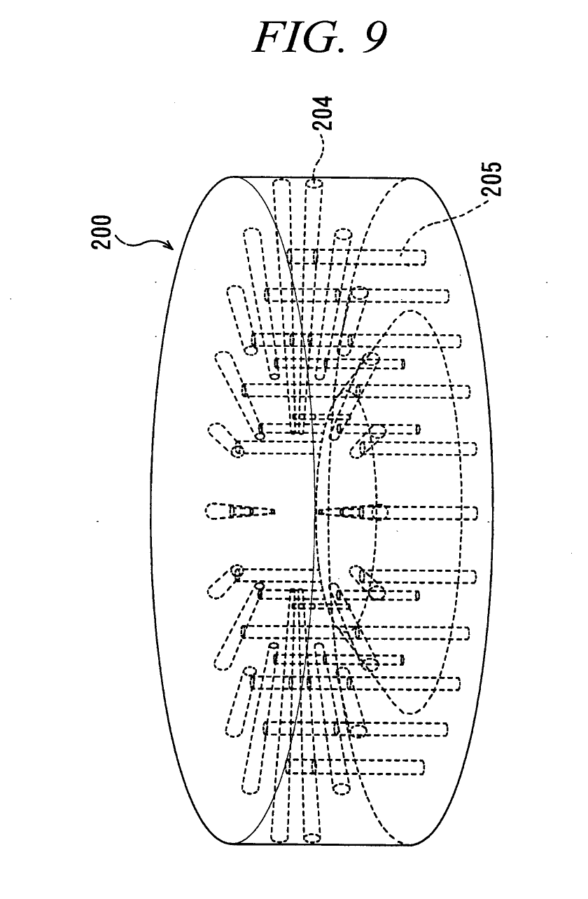

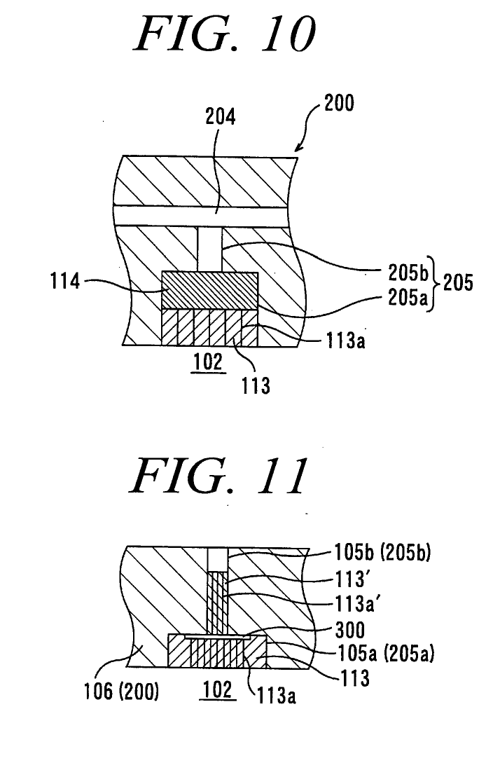

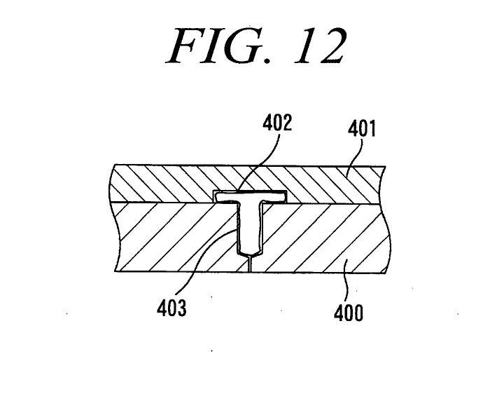

### EXPLANATION OF CODES

101: Gas exhaust ports
102: Processing chamber
103: Target substrate
104: Holding table
105: Vertical hole
105a: First vertical hole
105b: Second vertical hole
106: Shower plate
107: Sealing O-ring
108: Cover plate
109: Sealing O-ring
110: Gas inlet port
111: Gas supply hole
112: Space
113, 113′: Ceramics member
113a, 113a′: Gas discharge hole
114: Porous ceramics sintered body (porous gas flowing body)
115: Chamfering process
116: Slot plate
117: Wavelength shortening plate
118: Coaxial waveguide
119: Metal plate
120: Cooling flow path
121: Lower shower plate
121a: Gas flow path
121b: Nozzle
121c: Opening
122: Processing gas supply port
123: RF power supply
200: Shower plate
201: Wall surface
202: Sealing O-ring
203: Ring-shaped space
204: Horizontal hole
205: Vertical hole
205a: First vertical hole
205b: Second vertical hole
300: Recess

What is claimed is:

1. A shower plate disposed in a plasma processing apparatus and provided with a plurality of gas discharge holes for discharging a plasma excitation gas to generate plasma in the apparatus,
wherein at least one gas discharge hole is provided in ceramics members, each being installed in each of a multiplicity of vertical holes opened in the shower plate, and an aspect ratio of a length of the gas discharge hole to a hole diameter thereof (length/hole diameter) is equal to or greater than about 20.

2. The shower plate of claim 1, wherein the diameter of the gas discharge hole is equal to or less than twice a sheath thickness of the plasma generated directly under the shower plate, and the length of the gas discharge hole is longer than a mean free path of electrons in a processing chamber.

3. The shower plate of claim 1, wherein end portions at a gas introducing side of the vertical hole is chamfered.

4. The shower plate of claim 1, wherein the vertical hole has different diameters in a length direction thereof.

5. The shower plate of claim 4, wherein a diameter of a gas introducing side of the vertical hole is larger than a diameter of a gas discharging side thereof.

6. The shower plate of claim 4, wherein a diameter of a gas introducing side of the vertical hole is smaller than a diameter of a gas discharging side thereof.

7. The shower plate of claim 4, wherein the ceramics member is installed at both a large-diameter portion and a small-diameter portion of the vertical hole.

8. The shower plate of claim 1, wherein an end surface of a gas discharging side of the ceramics member is approximately on the same plane as a surface of a gas discharging side of the shower plate.

9. The shower plate of claim 8, wherein an end surface of a gas introducing side of the ceramics member is in the inside of the vertical hole.

10. The shower plate of claim 9, wherein a porous ceramics member is installed at a gas introducing side from the end surface of the gas introducing side of the ceramics member and in the inside the vertical hole.

11. The shower plate of claim 1, wherein a number of gas discharge holes is provided in each ceramics member.

12. The shower plate of claim 6, wherein a first ceramics member is installed in a small-diameter portion of the gas introducing side of the vertical hole; a second ceramics member is installed in a large-diameter portion of the gas discharging side of the vertical hole; a recess is provided at a gas introducing side of the second ceramics member; the plasma excitation gas discharged from gas discharge holes of the first ceramics member is diffused into and filled in the recess and then is discharged into the plasma processing apparatus from gas discharge holes of the second ceramics member; and the number of the gas discharge holes of the second ceramics member is larger than the number of the gas discharge holes of the first ceramics member.

13. A manufacturing method for a shower plate comprising:
inserting a green body, a debound body, a tentatively sintered body or a sintered body of a ceramics member having one or more gas discharge holes into a vertical hole of a green body, a debound body or a tentatively sintered body of a shower plate having the vertical hole formed by molding raw material powder, and then sintering them at the same time.

14. A plasma processing apparatus including a shower plate as claimed in claim 1.

15. A plasma processing method comprising:
supplying a plasma excitation gas into a plasma processing apparatus by using a shower plate as claimed in claim 1;
generating plasma by exciting the supplied plasma excitation gas by microwave; and
performing oxidation, nitridation, oxynitridation, CVD, etching or plasma irradiation on a substrate by using the plasma.

16. An electronic device manufacturing method comprising a process for processing a substrate by a plasma processing method as claimed in claim 15.
